(19) United States
(12) Patent Application Publication
(10) Pub. No.: US 2023/0192478 A1
(43) Pub. Date: Jun. 22, 2023

(54) Semiconductor Device and Method of Making a MEMS Semiconductor Package

(71) Applicant: UTAC Headquarters Pte. Ltd., Singapore (SG)

(72) Inventor: Phongsak Sawasdee, Bangkok (TH)

(73) Assignee: UTAC Headquarters Pte. Ltd., Singapore (SG)

(21) Appl. No.: 18/058,565

(22) Filed: Nov. 23, 2022

Related U.S. Application Data
(60) Provisional application No. 63/265,723, filed on Dec. 20, 2021.

(51) Int. Cl. B81B 7/00; B81C 1/00

(52) U.S. Cl. CPC B81B 7/0061; B81B 7/0064; B81B 7/0074; B81C 1/00309; B81B 2201/0214; B81B 2201/0257; B81B 2201/0264; B81B 2207/07; B81C 2203/0145

(57) ABSTRACT

A semiconductor device includes a substrate. A first semiconductor die including a microelectromechanical system (MEMS) is disposed over the substrate. A lid is disposed on the substrate around the first semiconductor die. A first encapsulant is deposited over the substrate and lid. A second encapsulant is deposited into the lid.

### CLAIM OF DOMESTIC PRIORITY

The present application claims the benefit of U.S. Provisional Application No. 63/265,723, filed Dec. 20, 2021, which application is incorporated herein by reference.

### FIELD OF THE INVENTION

The present invention relates in general to semiconductor devices and, more particularly, to a semiconductor device and method of making a microelectromechanical system (MEMS) semiconductor package.

### BACKGROUND OF THE INVENTION

Semiconductor devices are commonly found in modern electronic products. Semiconductor devices perform a wide range of functions, such as signal processing, high-speed calculations, sensors, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often include MEMS. MEMS applications typically require special packaging to allow the MEMS to function properly within the package. While many options exist for MEMS packaging, the existing options are suboptimal and many improvements are possible. Manufacturing MEMS packages can be expensive and complicated. Therefore, a need exists for an improved MEMS semiconductor package and methods of making.

### BRIEF DESCRIPTION OF THE DRAWINGS

FIGS. 1a-1c illustrate a semiconductor wafer with a plurality of semiconductor die separated by a saw street;

FIGS. 2a-2f illustrate a method of making a first MEMS package;

FIG. 3 illustrates a completed first MEMS package;

FIG. 4 illustrates the first MEMS package with stacked die;

FIGS. 5a-5c illustrate a method of making a second MEMS package;

FIG. 6 illustrates a completed second MEMS package;

FIG. 7 illustrates the second MEMS package with stacked die;

FIGS. 8a-8d illustrate forming a MEMS package similar to the first MEMS package with a secondary die;

FIGS. 9a and 9b illustrate forming a MEMS package similar to the second MEMS package with a secondary die; and

FIG. 10 illustrates incorporating one of the MEMS packages into an electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

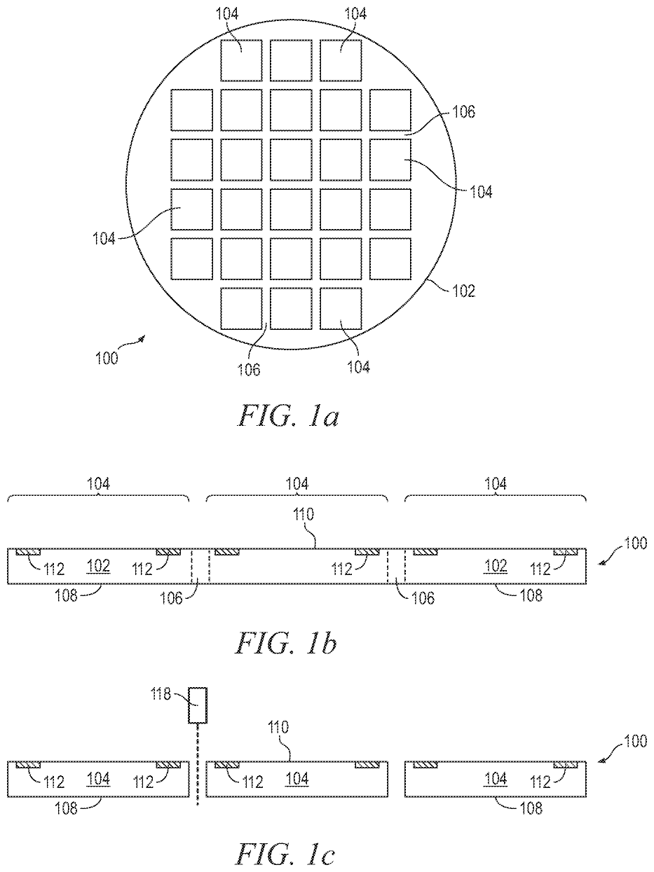

FIG. 1a shows semiconductor wafer or substrate 100 with a base substrate material 102, such as silicon (Si), silicon carbide (SiC), cubic silicon carbide (3C-SiC), germanium, aluminum phosphide, aluminum arsenide, gallium arsenide, gallium nitride, indium phosphide, diamond, and all families of III-V and II-VI semiconductor materials for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1B shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as diodes, inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) post singulation.

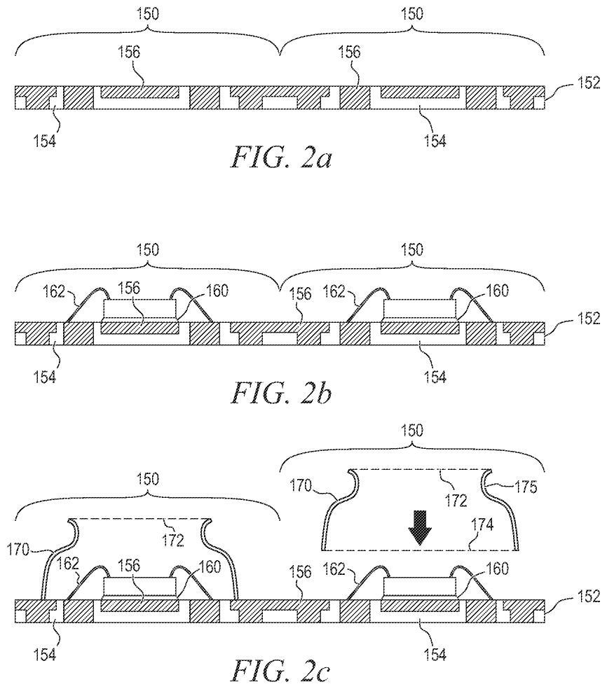

FIGS. 2a-2f illustrate manufacturing semiconductor packages 150 with semiconductor die 104. In one embodiment, semiconductor die 104 is a MEMS die including a microelectromechanical system (MEMS) formed on the die. The MEMS can be, for example, a pressure sensor, gas sensor, microphone, or any other suitable device.

FIG. 2a shows a substrate 152 used to form packages 150. Substrate 152 is a molded interconnect substrate (MIS) or dielectric laminate substrate in some embodiments. While a small substrate 152 suitable for forming two packages 150 is shown, hundreds or thousands of units are commonly formed together on a single substrate, using the same steps described herein performed en masse. Substrate 152 includes one or more insulating layers 154 interleaved with one or more conductive layers 156. Insulating layer 154 is a core insulating board in one embodiment, with conductive layers 156 patterned over the top and bottom surfaces, e.g., a copper-clad laminate substrate. Conductive layers 156 also include conductive vias electrically coupled through insulating layers 154. Substrate 152 can include any number of conductive and insulating layers interleaved over each other. A solder mask or passivation layer can be formed over either side of substrate 152. Any suitable type of substrate or leadframe is used for substrate 152 in other embodiments.

Forming semiconductor package 150 on substrate 152 begins with mounting semiconductor die 104 in FIG. 2b. Any number, type, and combination of semiconductor die and other electrical components, such as discrete active or passive components, can be mounted on or over substrate 152 to make packages 150. Semiconductor die 104 is disposed over substrate 152 with a pick-and-place or other suitable method or machine with active surface 110 oriented away from the substrate. Semiconductor die 104 is optionally disposed on a die pad formed as part of conductive layer 156. Die attach adhesive 160 is optionally used to hold semiconductor die 104 in place. Die attach adhesive 160 is cured if needed after semiconductor die 104 are placed.

A plurality of bond wires 162 is formed between active surface 110 and contact pads of conductive layer 156 on substrate 152. Bond wires 162 electrically connect semiconductor die 104 to substrate 152. In other embodiments, semiconductor die 104 are flip-chip mounted onto substrate 152 with solder bumps, stud bumps, conductive pillars, or another suitable interconnect structure.

In FIG. 2c, lids 170 are disposed onto substrate 152 over and around semiconductor die 104 using a pick-and-place machine or other suitable mechanism. Each lid 170 has a top lip defining a top opening 172, a bottom lip defining a bottom opening 174, and sidewalls extending from the bottom lip to the top lip. The sidewalls of lid 170 extend horizontally in a square, circle, or other shape to completely surround semiconductor die 104 and bond wires 162 once the lid is disposed on substrate 152. A hollow middle cavity defined by the sidewalls of lid 170 extends from top opening 172 to bottom opening 174. Lids 170 are formed from copper, aluminum, gold, steel, another suitable metal or combination of metals, plastic, or another suitable material. Lids 170 are formed by molding, stamping, printing, forming, or another suitable process. Lid 170 provides a level of EMI shielding when formed from metal, and may be grounded through conductive layers 156 to improve shielding.

Lids 170 are disposed such that semiconductor die 104 goes through bottom opening 174 as the bottom lip is moved towards and set on substrate 152. The bottom lip of lid 170 physically contacts substrate 152 in a path that surrounds semiconductor die 104 and bond wires 162 in plan view. An adhesive can be disposed onto substrate 152 or lid 170 in advance to attach the lid to the substrate. The adhesive is heated, cured, or both after lids 170 are in place as needed for the particular adhesive being used. In another embodiment, lids 170 are soldered onto conductive layer 156 or attached to substrate 152 using another suitable means.

Lids 170 include a neck 175 where the sidewall of the lid extends inward around the lid near top opening 172. Even with neck 175 extending inward, the footprints of lid 170 and semiconductor die 104 remain completely nonoverlapping. Keeping lid 170 from overlapping semiconductor die 104 in plan view improves performance of some MEMs sensors by reducing resistance of stimuli to the die. In other embodiments, the opening in neck 175 is smaller than an underlying semiconductor die. Sidewalls of lid 170 extending inward toward neck 175 improves electro-magnetic shielding performance of the lid with respect to die 104 and bond wires 162.

Forming bond wires 162 prior to disposing lid 170 over semiconductor die 104 eases manufacturing requirements for the bond wire formation because the process is not restricted by the presence of a lid. A lid with a smaller opening on top is usable because the bond wires no longer need to be formed through the lid opening.

FIG. 2d shows a first encapsulant 180 deposited into lid 170. Encapsulant 180 can be polymer composite material, such as epoxy resin, epoxy acrylate, or another suitable polymer. An appropriate filler can be used if desired. Encapsulant 180 is non-conductive, provides structural support, and environmentally protects the semiconductor device from external elements and contaminants. Encapsulant 180 is gel in one embodiment. Encapsulant 180 is cured if needed.

Encapsulant 180 fills lid 170 at least far enough to cover semiconductor die 104 and bond wires 162. A top surface 182 of encapsulant 180 includes a convex or other curve to modify light flowing through top opening 172 before hitting semiconductor die 104 in cases where semiconductor die is light sensitive. In other embodiments, top surface 182 is simply concave due to the interaction of surface tension with sidewalls of lid 170 prior to the curing of encapsulant 180.

In FIG. 2e, a second encapsulant 190 is deposited over substrate 152 around the outsides of lids 170. Encapsulant 190 is deposited using paste printing, compressive molding, transfer molding, liquid encapsulant molding, vacuum lamination, spin coating, or another suitable applicator. Encapsulant 190 can be polymer composite material, such as epoxy resin, epoxy acrylate, or polymer with or without a filler. Encapsulant 190 is non-conductive, provides structural support, and environmentally protects the semiconductor device from external elements and contaminants. Encapsulant 190 completely covers outer surfaces of lids 170 and any remaining exposed portions of the top surface of substrate 152. Encapsulant 190 follows neck 175 inward, which helps keep lid 170 on substrate 152. Encapsulant 190 is deposited using film-assisted molding or another suitable method to leave the top surface of the second encapsulant planar and even with the tops of lids 170. Encapsulant 190 is cured if needed.

In one embodiment, first encapsulant 180 is a material that is transmissive of some stimulus desired to be detected by the MEMS on semiconductor die 104, e.g., light, sound, certain particles, etc. Top opening 172 allows the stimulus into lid 170. First encapsulant 180 allows the stimulus to reach semiconductor die 104 while still providing physical support to bond wires 162 and protection from undesired physical stimulus that could damage the semiconductor die. First encapsulant 180 may be softer and not as protective of semiconductor die 104 as second encapsulant 190, which is much more rigid and protective. Lid 170 keeps first encapsulant 180 contained to just the immediate vicinity of semiconductor die 104, allowing second encapsulant 190 to be deposited around the first encapsulant to protect the resulting package 150 as a whole.

Solder bumps 192 are optionally formed on the bottom of substrate 152, opposite semiconductor die 104, after encapsulant 190 is deposited or at any other stage of the manufacturing process. To form solder bumps 192, an electrically conductive bump material is deposited over conductive layer 156 using an evaporation, electrolytic plating, electroless plating, ball drop, or screen printing process. The bump material can be Al, Sn, Ni, Au, Ag, lead (Pb), Bismuth (Bi), Cu, solder, and combinations thereof, with an optional flux solution. For example, the bump material can be eutectic Sn/Pb, high-lead solder, or lead-free solder.

The bump material is bonded to conductive layer 156 using a suitable attachment or bonding process. In one embodiment, the bump material is reflowed by heating the material above its melting point to form balls or bumps 192. In one embodiment, bump 192 is formed over an under-bump metallization (UBM) having a wetting layer, barrier layer, and adhesion layer. Bump 192 can also be compression bonded or thermocompression bonded to conductive layer 156. Bump 192 represents one type of interconnect structure that can be formed over conductive layer 156. The interconnect structure can also use bond wires, conductive paste, stud bump, micro bump, lands, or other electrical interconnect.

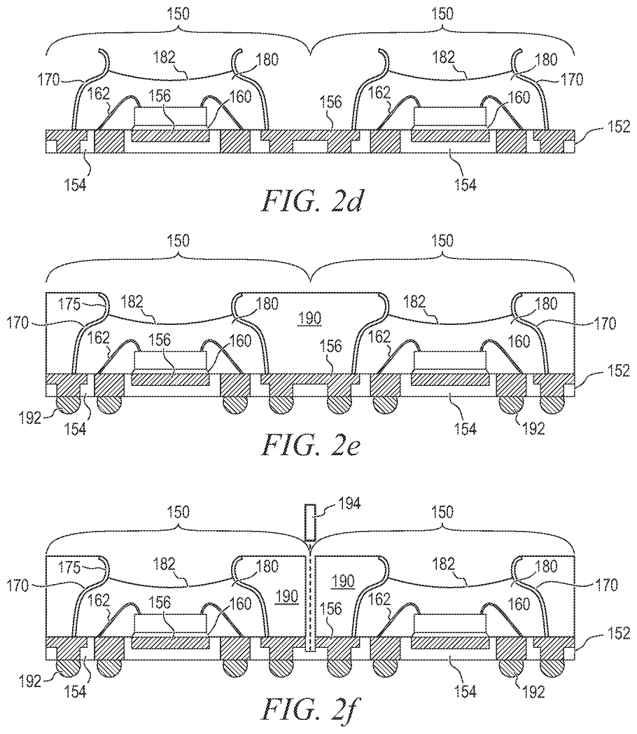

In FIG. 2f, packages 150 are singulated from each other by cutting through encapsulant 190 and substrate 152 between lids 170 using a laser cutting tool, water cutting tool, saw blade, or other cutting mechanism 194. FIG. 3 shows a completed package 150. Package 150 includes semiconductor die 104 with a MEMS on or in the semiconductor die. Top opening 172 of lid 170 and first encapsulant 180 allow an external stimulus to reach semiconductor die 104. Second encapsulant 190 physically protects package 150. Bumps 192 allow package 150 to be incorporated into a larger electronic device by reflowing the bumps onto a PCB of the electronic device.

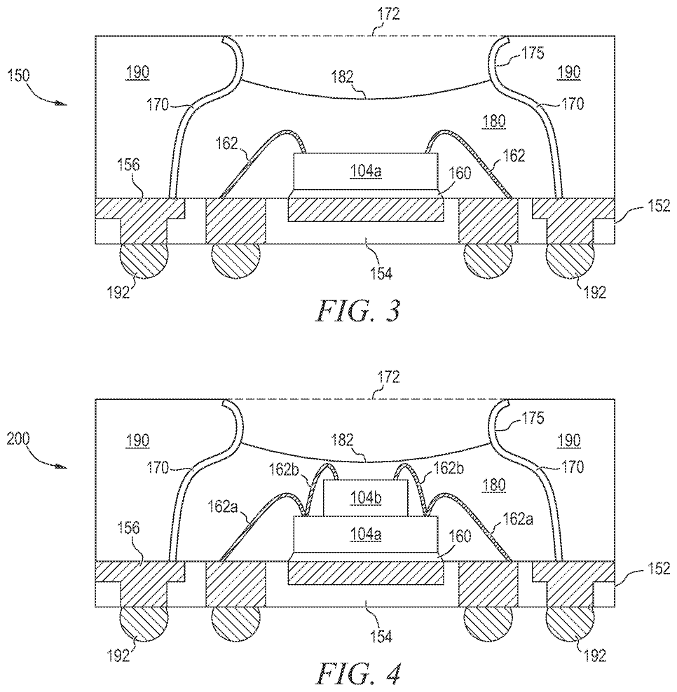

FIG. 4 shows another embodiment as semiconductor package 200 with a pair of stacked semiconductor die 104a and 104b. In one embodiment, semiconductor die 104b is a MEMS die while semiconductor die 104a is a semiconductor die with a supporting function, such as a processing unit to control and communicate with the MEMS. Bond wires 162a electrically connect semiconductor die 104a to substrate 152 while bond wires 162b electrically connect semiconductor die 104b to semiconductor die 104a. Semiconductor die 104b may also be directly coupled to substrate 152 by other bond wires.

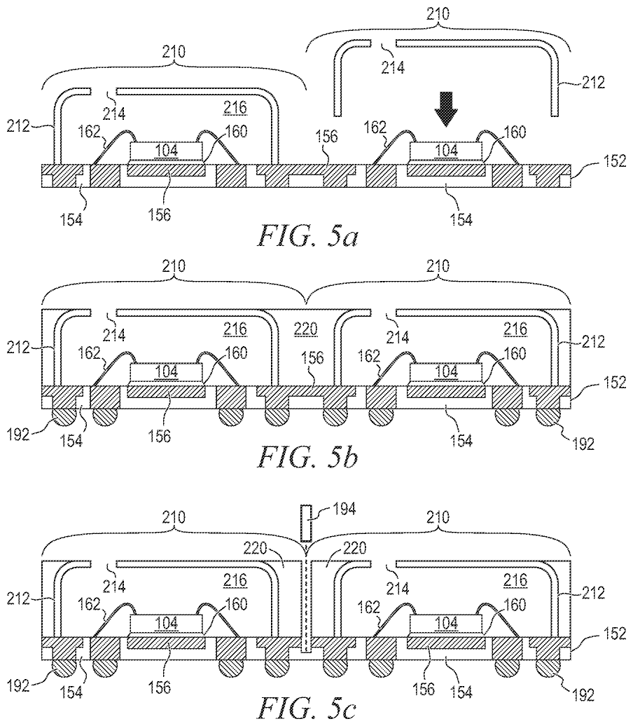

FIGS. 5a-5c illustrate another embodiment where semiconductor packages 210 are formed with lid 212. FIG. 5a continues from FIG. 2b with lids 212 disposed over semiconductor die 104. Semiconductor die 104 may have a different type of MEMS when used with lid 212 than with lid 170. Lids 212 have a top portion that extends over semiconductor die 104 and an opening 214 formed in the top portion to allow a stimulus into cavity 216 within the lid. Opening 214 is formed completely outside a footprint of semiconductor die 104. The top portion of lid 212 completely overlaps the entire footprint of semiconductor die 104. Lids 212 are manufactured from any of the materials, and using any of the processes, mentioned above for lid 170. Lid 212 can be held onto substrate 152 using an adhesive or solder as described above for lid 170.

In FIG. 5b an encapsulant 220 is deposited over lids 212 and substrate 152. Encapsulant 220 is deposited using paste printing, compressive molding, transfer molding, liquid encapsulant molding, vacuum lamination, spin coating, or another suitable applicator. Encapsulant 220 can be polymer composite material, such as epoxy resin, epoxy acrylate, or polymer with or without a filler. Encapsulant 220 is non-conductive, provides structural support, and environmentally protects the semiconductor device from external elements and contaminants. Encapsulant 220 completely covers outer surfaces of lids 212 and any portions of the top surface of substrate 152 outside the lids. Encapsulant 220 is deposited using film-assisted molding or another suitable method to leave the top surface of the encapsulant coplanar with the top portions of lids 212. Cavity 216 within each lid 212 remains free of encapsulant 220.

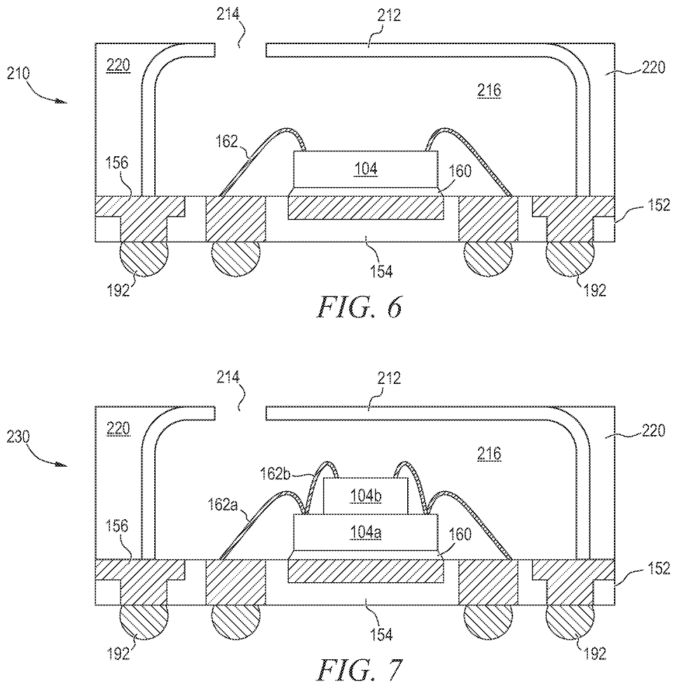

In FIG. 5c, packages 210 are singulated from each other by cutting through encapsulant 220 and substrate 152 between lids 212 using cutting tool 194. FIG. 6 shows a completed package 210. Package 210 includes semiconductor die 104 with a MEMS on or in the semiconductor die. Lid 212 defines a cavity 216 that remains connected to ambient via opening 214. Sound, particles, and other stimuli enters cavity 216 through opening 214 to be detected by semiconductor die 104. Cavity 216 remains free of encapsulant and other materials that might block a stimulus from reaching semiconductor die 104.

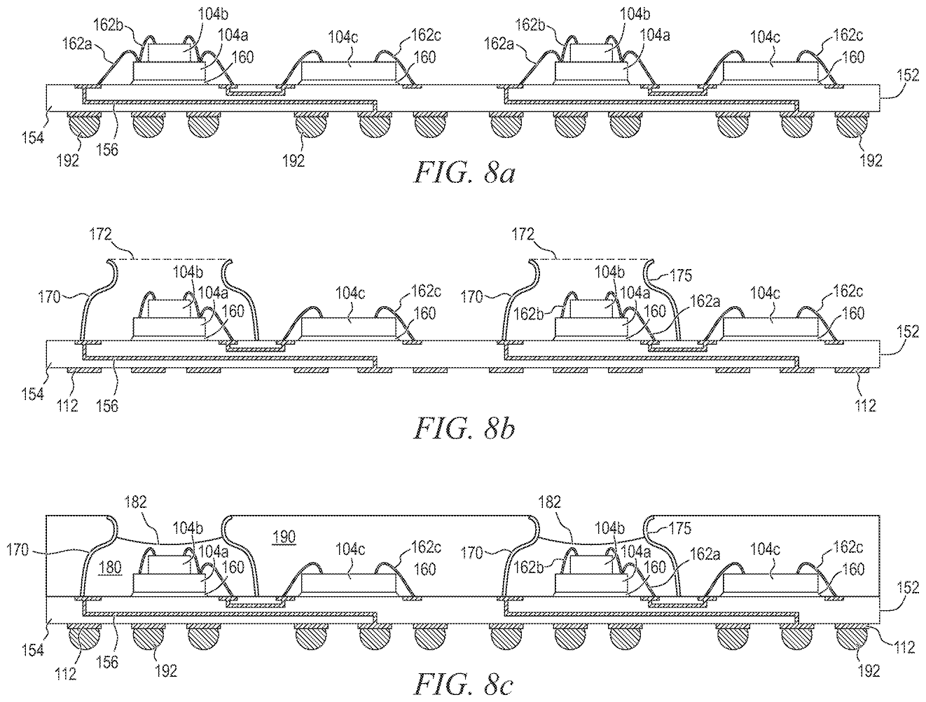

FIG. 7 shows another embodiment as semiconductor package 230 with a pair of stacked semiconductor die 104a and 104b. In one embodiment, semiconductor die 104b is a MEMS die while semiconductor die 104a is a semiconductor die with a supporting function, such as a processing unit to control and communicate with the MEMS. Bond wires 162a electrically connect semiconductor die 104a to substrate 152 while bond wires 162b electrically connect semiconductor die 104b to semiconductor die 104a. Semiconductor die 104b may also be directly coupled to substrate 152 by other bond wires.

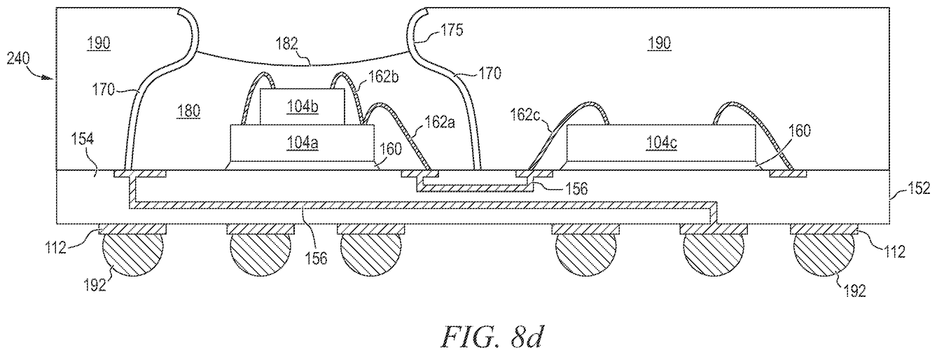

FIGS. 8a-8d illustrate an embodiment with lid 170 and a separate semiconductor die outside of the lid. FIG. 8a shows substrate 152 with stacked die 104a and 104b, and a third die 104c disposed on the substrate adjacent to the stacked die. Substrate 152 has conductive layers 156 configured to electrically couple semiconductor die 104c to the stacked die 104a-104b, and all three die coupled to solder bumps 192 as desired for the intended functionality of the package being manufactured.

In FIG. 8b, lid 170 is disposed over and around stacked die 104a-104b as described above. In other embodiments, stacked die can be used outside of lid 170, only a single die can be used within the lid, or any combination of stacked or single die can be used. Any desired electrical components can be disposed on substrate 152 within or without lid 170. FIG. 8c shows first encapsulant 180 and second encapsulant 190 deposited as described above. First encapsulant 180 is deposited into and contained by lid 170. Second encapsulant 190 is deposited directly on and completely surrounds semiconductor die 104c. The panel of devices in FIG. 8c is singulated to form the completed package 240 in FIG. 8d. Package 240 includes stacked die 104a and 104b within lid 170 and a single die 104c outside of the lid. Semiconductor die 104a-104c are all three interconnected and operate together.

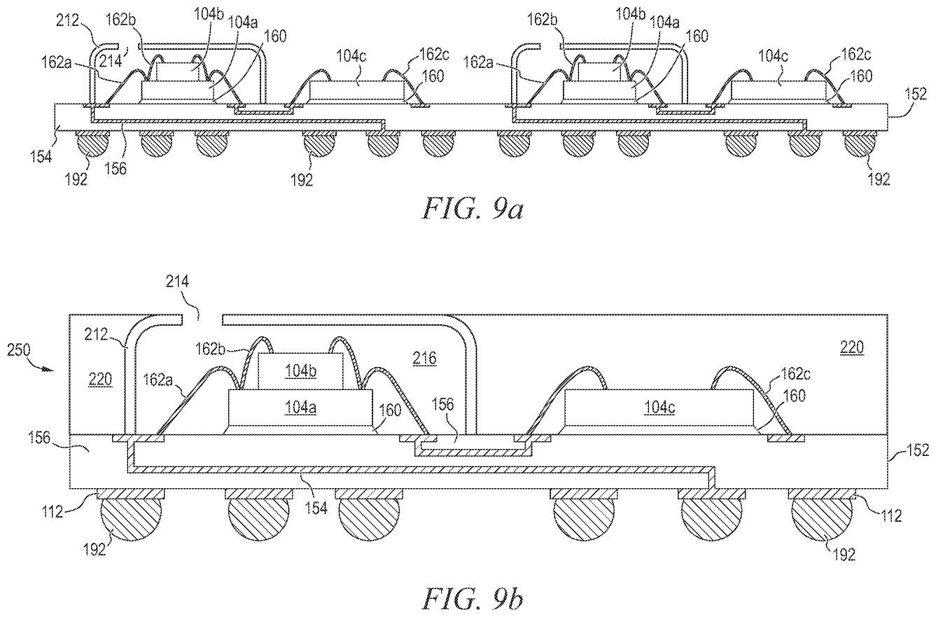

FIG. 9a shows a similar embodiment with lid 212. As above, a stacked die or single die can be used in any combination inside and outside of lid 212. FIG. 9b shows a completed package 250 after depositing encapsulant 220 and singulating.

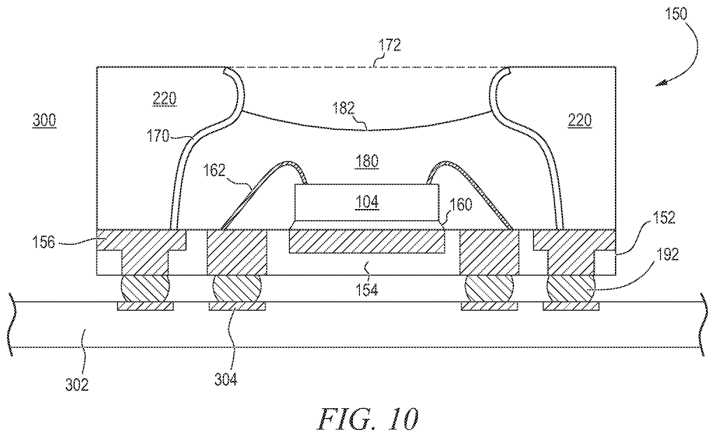

FIG. 10 illustrates integrating the above-described semiconductor packages, e.g., semiconductor package 150, into a larger electronic device 300. FIG. 10 is a partial cross-section of package 150 mounted onto a printed circuit board (PCB) or other substrate 302 as part of electronic device 300. Bumps 192 are reflowed onto conductive layer 304 of PCB 302 to physically attach and electrically connect package 150 to the PCB. In other embodiments, thermocompression or other suitable attachment and connection methods are used. In some embodiments, an adhesive or underfill layer is used between package 150 and PCB 302. Semiconductor die 104 is electrically coupled to conductive layer 304 through substrate 152 to allow use of the functionality of package 150 by the larger system.

Electronic device 300 can have one type of semiconductor package, or multiple types of semiconductor packages, depending on the application. Electronic device 300 can be a stand-alone system that uses the semiconductor packages to perform one or more electrical functions. Alternatively, electronic device 300 can be a subcomponent of a larger system. For example, electronic device 300 can be part of a tablet computer, cellular phone, digital camera, communication system, or other electronic device. Package 150 can operate as, e.g., a pressure or gas sensor for electronic device 300.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a substrate;
disposing a first semiconductor die including a microelectromechanical system (MEMS) over the substrate;
forming a bond wire to couple the first semiconductor die to the substrate;
disposing a lid on the substrate around the first semiconductor die and bond wire;
depositing a first encapsulant over the substrate and lid; and
depositing a second encapsulant into the lid.

2. The method of claim 1, wherein a footprint of the lid is nonoverlapping with a footprint of the semiconductor die after disposing the lid over the first semiconductor die.

3. The method of claim 1, wherein the first encapsulant and second encapsulant are different materials.

4. The method of claim 1, wherein the second encapsulant is a gel.

5. The method of claim 1, further including disposing a second semiconductor die on the substrate outside the lid.

6. The method of claim 1, further including stacking a second semiconductor die on the first semiconductor die.

7. The method of claim 1, further including forming a conductive bump on the substrate opposite the first semiconductor die.

8. A method of making a semiconductor device, comprising:
providing a substrate;
disposing a first semiconductor die including a microelectromechanical system (MEMS) over the substrate;
disposing a lid over the first semiconductor die; and
depositing a first encapsulant over the substrate and lid.

9. The method of claim 8, further including depositing a second encapsulant into the lid.

10. The method of claim 9, wherein the first encapsulant and second encapsulant are different materials.

11. The method of claim 9, wherein the second encapsulant is a gel.

12. The method of claim 8, further including disposing a second semiconductor die on the substrate outside the lid.

13. The method of claim 8, further including stacking a second semiconductor die on the first semiconductor die.

14. The method of claim 8, further including forming a bond wire coupled between the substrate and first semiconductor die prior to disposing the lid over the first semiconductor die.

15. A semiconductor device, comprising:
a substrate;
a first semiconductor die including a microelectromechanical system (MEMS) disposed over the substrate;
a lid disposed over the first semiconductor die; and
a first encapsulant deposited over the substrate and lid.

16. The semiconductor device of claim 15, further including a second encapsulant deposited into the lid.

17. The semiconductor device of claim 15, wherein the first encapsulant and second encapsulant are different materials.

18. The semiconductor device of claim 15, wherein the second encapsulant is a gel.

19. The semiconductor device of claim 15, further including a second semiconductor die disposed on the substrate outside the lid.

20. The semiconductor device of claim 15, further including a second semiconductor die stacked on the first semiconductor die.
